(19) United States
(12) Patent Application Publication
(10) Pub. No.: US 2011/0182035 A1
(43) Pub. Date: Jul. 28, 2011

(54) ELECTRONIC DEVICE

(76) Inventor: Takashi Yajima, Fukaya-shi (JP)

(21) Appl. No.: 12/939,847

(22) Filed: Nov. 4, 2010

(30) Foreign Application Priority Data
Jan. 28, 2010 (JP) JP 2010-016235

(51) Int. Cl. H05K 7/20

(52) U.S. Cl. 361/717

(57) ABSTRACT

An electronic apparatus includes: a semiconductor device including an electrically conductive portion to be grounded, the semiconductor device being configured to be mounted on a circuit board; a heat sink configured to radiate heat generated by the semiconductor device; a fastener configured to fasten the heat sink to the circuit board; and a first spring member wound around the fastener to electrically connect the heat sink to the electrically conductive portion.

### CROSS-REFERENCE TO THE RELATED APPLICATION(S)

The present application is based upon and claims priority from prior Japanese Patent Application No. 2010-016235, filed on Jan. 28, 2010, the entire contents of which are incorporated herein by reference.

### FIELD

Embodiments described herein generally relate to an electronic device having a heat sink.

### BACKGROUND

Semiconductor devices (e.g., a central processing unit (CPU)) having a high processing speed are demanded for digital media apparatuses such as a digital television set. Heat values during operation have been increasing every year. Excessively heated high-temperature semiconductor devices are highly likely to malfunction. Thus, each of semiconductor devices with high power consumption and high heat values has been provided with a heat sink. Generally, heat sinks are made of highly heat-conductive metal such as aluminum, and fixed onto semiconductor devices with, e.g., plastic fasteners.

As described above, the heat sink is an electrical conductor and can be an electric charge path. Thus, the heat sink can be a discharging-destination to which static electricity is discharged. Accordingly, when an electrostatic discharge (ESD) occurs, inescapable static electricity is discharged to a terminal or the like of a surrounding semiconductor device via the heat sink. Thus, the surrounding semiconductor device may seriously be damaged (e.g., the destruction, malfunction, or the like of the semiconductor device may be caused).

From the viewpoint of avoiding the ESD problem, the heat sink is connected to a ground potential terminal (abbreviated as GND). An example of the heat sink is disclosed in JP-A-2006-080453. According to this technique, static electricity discharged to the heat sink flows into the GND that is lower in electric potential than the semiconductor device. Thus, this technique may avoid damaging the semiconductor device.

### BRIEF DESCRIPTION OF THE DRAWINGS

A general configuration that implements the various features of the present invention will be described with reference to the drawings. The drawings and the associated descriptions are provided to illustrate embodiments of the invention and not to limit the scope of the invention.

FIG. 1 is a perspective view illustrating an external view of an electronic apparatus according to an embodiment of the invention.

FIG. 2 is a cross-sectional view illustrating the electronic apparatus according to the embodiment.

FIG. 3 is a perspective view illustrating an application example of the electronic apparatus according to the embodiment.

### DETAILED DESCRIPTION

According to the embodiments described herein, there is provided an electronic apparatus including: a semiconductor device including an electrically conductive portion to be grounded, the semiconductor device being configured to be mounted on a circuit board; a heat sink configured to radiate heat generated by the semiconductor device; a fastener configured to fasten the heat sink to the circuit board; and a first spring member wound around the fastener to electrically connect the heat sink to the electrically conductive portion.

Embodiments according to the present invention will be described in detail with reference to the accompanying drawings. The scope of the claimed invention should not be limited to the examples illustrated in the drawings and those described in below.

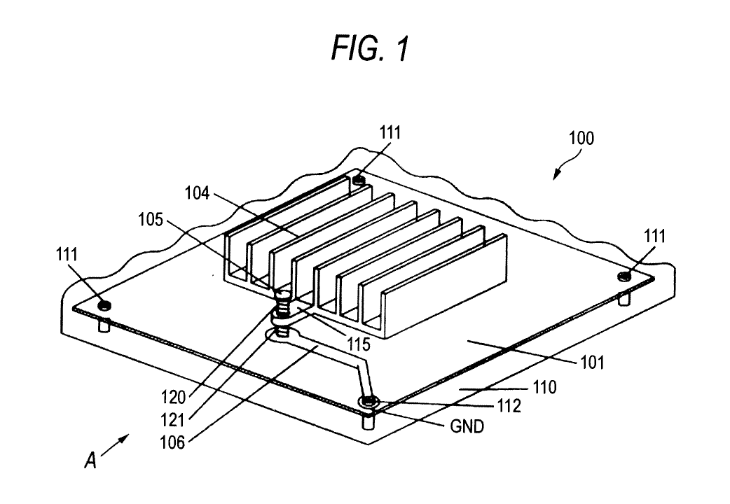

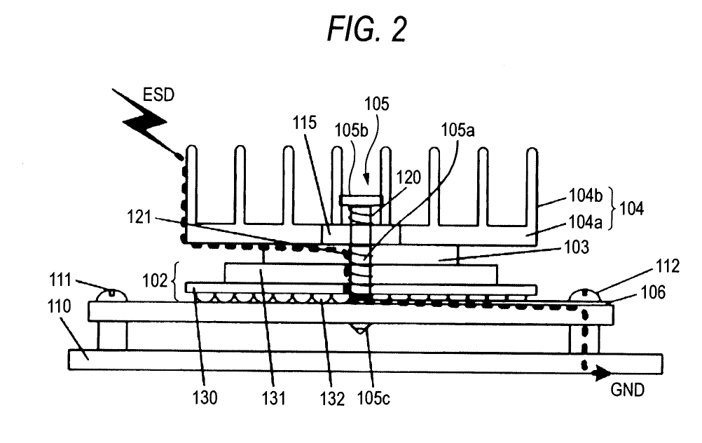

FIG. 1 is a perspective view illustrating, as an example of the invention, a configuration of a part of a printed board unit (electronic device 100), in which a semiconductor device provided with a heat sink fixed thereto is mounted on a printed board. FIG. 2 is a view illustrating the printed board unit, taken from a direction indicated by arrow A illustrated in FIG. 1.

As illustrated in FIGS. 1 and 2, the electronic device 100 mainly includes a printed board 101, a semiconductor device 102 mounted on the printed board 101, a heat sink 104 provided on the semiconductor device 102 via a thermally conductive sheet 103, a pillar-shaped fastener (columnar fastener) 105 for fixing the heat sink 104 to the printed board 101, a copper foil layer 106 provided around the fastener 105 on the printed board 101, a case 110 on which the printed board 101 and the like are mounted, several screws 111 for fixing the printed board 101 to the case 110, and screws 112 for connecting the copper foil layer 106 to the GND and for fixing the printed board 101 to the case 110.

The fastener 105 is pillar-shaped and includes a shank portion 105a around which a fixing spring 120 and a connecting spring 121 are spirally wound, a head portion 105b configured to be larger in diameter than the shank portion 105a, and a protrusion portion 105c configured as a tip end part of the shank portion 105a to be larger in diameter than the shank portion 105a and to engage with the printed board 101. The protrusion portion 105c protrudes from the back surface of the printed board 101 when the fastener 105 is fixed to the printed board 101.

A mounting portion 115 having an opening into which the fastener 105 is inserted extends outwardly from a part of the heat sink 104. The present embodiment is configured by forming the mounting portion 115 and the heat sink 104 integrally with each other. However, the mounting portion 115 can be provided as a separate member from the heat sink 104.

The fixing spring 120 for fixing the heat sink 104 is provided between the top surface of the mounting portion 115 and the head portion 105b. The connecting spring 121 for electrically connecting the fastener 105 and the copper foil layer 106 to each other is provided between the other surface of the mounting portion 115 and the front surface of the printed board 101.

Although not illustrated in the drawings, a large number of electronic components, such as semiconductor integrated circuits (ICs), resistors, and capacitors, are mounted on the surface of the printed board 101. The components are interconnected to one another by wiring.

Various types of semiconductor devices can be used as those (IC chips) to be mounted on the printed board 101. In the present embodiment, a ball grid array (BGA) type semiconductor device 102 is mounted thereon by way of example. As illustrated in FIG. 2, the BGA type semiconductor device 102 includes a printed board 130, a semiconductor element portion 131 that is provided with a large number of semiconductor elements and resin-sealed, and a plurality of input/output electrodes 132 that are placed on the back surface of the printed board 130 and formed of solder or the like. The semiconductor device 102 can be formed of a single element such as a transistor.

The thermally conductive sheet 103 includes, e.g., a silicon sheet or graphite sheet, which has insulation properties and flexibility and is formed of a high-thermal-conductivity material. Thus, the arrangement of the thermally conductive sheet 103 between the heat sink 104 and the semiconductor device 102 is preferable from the viewpoint of efficiently radiating from the heat sink 104 heat generated in the semiconductor device 102 during operation. The surface of the thermally conductive sheet 103 can have adhesion properties. In such a configuration, the heat sink 104 and the semiconductor device 102 are temporarily fixed by the thermally conductive sheet 103. A double-sided tape or the like can be disposed between the thermally conductive sheet 103 and the heat sink 104 and between the thermally conductive sheet 103 and the semiconductor device 102 to fix each of these components.

The heat sink 104 is formed of high-thermal-conductivity metal (e.g., aluminum or aluminum-alloy), which is a heat radiating device for performing diffusion-cooling of heat generated in the semiconductor device 102 during operation. From the viewpoint of enhancing heat radiation efficiency, a plurality of fins 104b are protruded in parallel perpendicularly from a substantially rectangular base substrate 104a. Preferably, the substrate 104a is equal to or larger in area than the semiconductor device 102. From the viewpoint of enhancing heat radiation efficiency, preferably, the heat sink 104 is provided in the vicinity of a target semiconductor device. In addition, preferably, the heat sink 104 is provided to overlap with at least a part of the semiconductor device 102, as illustrated in FIG. 2. In the present embodiment, a part of the substrate 104a extends therefrom. The extended part of the substrate 104a configures the mounting portion 115 in which the fastener 105 is mounted.

In addition, in the present embodiment, oxidation treatments (e.g., alumite treatments) are performed on the surfaces of the fins 104b and the front surface of the substrate 104a. Thus, a corrosion countermeasure is achieved. The alumite treatment is to form a colorless transparent oxide layer on the silver-white surface of aluminum. On the other hand, the alumite treatment is not performed on the back surface (surface at the side of the thermally conductive sheet 103) of the substrate 104a. Accordingly, the back-surface side of the substrate 104a is higher in conductivity than the front-surface side thereof. Thus, as an ESD countermeasure, the electrical connection between the back surface of the mounting portion 115 and the copper foil layer 106 (thus, the GND) via the connecting spring 121 is facilitated. Alternatively, at least a part of the back surface of the mounting portion 115, with which the connecting spring 121 makes contact, can be exposed by, e.g., cutting the back surface of the substrate 104a on which an alumite treatment is once performed. That is, the present embodiment is configured so that the connecting spring 121 is appropriately electrically connected at least to the back surface of the mounting portion 115. Accordingly, both the corrosion countermeasure and the ESD countermeasure for the heat sink 104 can be achieved. That is, from the viewpoint of the corrosion countermeasure and the ESD countermeasure, an oxidation treatment is performed on the surface of the heat sink 104 except at least a region of the mounting portion 115, with which the connecting spring 121 makes contact.

The fastener 105 is a pillar-shaped member for fixing the heat sink 104 onto the printed board 101. The fastener 105 is formed of an electrically non-conductive (insulating) material such as a plastic material. The fastener 105 can be formed of an electrically conductive material such as iron. However, the fastener 105 formed of the insulating material, such as a plastic material, is easier in processing than that formed of a metallic material. The former fastener 105 is lower in manufacturing-cost than the latter fastener 105. Thus, the former fastener 105 is preferable in manufacturing. The fastener 105 is inserted into the opening of the mounting portion 115 and an opening of the printed board 101. The protrusion portion 105c of the fastener 105 is caught on the back surface of the printed board 101 to thereby fix the fastener 105.

Although not illustrated in the drawings, a fastener 105 is also provided on the opposite side of the mounting portion 115 illustrated in FIG. 1. That is, in the present embodiment, another fastener 105 is also provided on the side opposed to the mounting portion 115 across the center of the heat sink 104. The fasteners 105 are fixed at two places to thereby fix the heat sink 104 onto the printed board 101.

The copper foil layer 106 is a conductive layer that can be formed simultaneously with, e.g., the formation of a large number of wires on the printed board 101. One end portion of the copper foil layer 106 is provided around the fastener 105 and electrically connected to the connecting spring 121. The other end portion is connected to the GND via the screw 112. That is, the copper foil layer 106 is grounded to the GND.

Each of the fixing spring 120 and the connecting spring 121 is formed of a metallic material (electrically conductive material) such as iron or aluminum. The fixing spring 120 is provided by being spirally wound around the shank portion 105a between the head portion 105b of the fastener 105 and the top surface of the mounting portion 115. The fixing spring 120 fixes the heat sink 104 onto the printed board 101 with an elastic force. The connecting spring 121 is provided by being wound around the shank portion 105a between the bottom surface (back surface) of the mounting portion 115 and the region of the copper foil layer 106 of the printed board 101. One end of the connecting spring 121 makes contact with the back surface of the mounting portion 115, while the other end thereof makes contact with the copper foil layer 106. Thus, the back surface of the mounting portion 115 (the back surface of the heat sink 104) is electrically connected to the copper foil 106 (thus, the CND) via the connecting spring 121.

The present embodiment is configured so that the fixing spring 120 differs in the magnitude of the elastic force from the connecting spring 121. That is, the present embodiment is configured so that the magnitude of the elastic force of the connecting spring 121 is less than that of the elastic force of the fixing spring 120. Thus, pressure is applied from the heat sink 104 to the semiconductor device 102, so that the heat sink 104 is closely contacted therewith. Accordingly, the heat sink 104 is appropriately fixed onto the printed board 101.

As described above, according to the present embodiment, the back surface of the heat sink 104 (the back surface of the mounting portion 115) and the copper foil layer 106 (thus, the GND) provided on the printed board 101 are electrically connected to each other via the connecting spring 121 wound around the fastener 105. Thus, static electricity discharged to the heat sink 104 by the discharge thereof due to unexpected static electricity flows into the copper foil layer 106 provided on the printed board 101 via the connecting spring 121. Then, the static electricity flows into the GND via the copper foil layer 106 and the screw 112. That is, when excessive static electricity is applied to the heat sink 104, the heat sink 104 is short-circuited to the GND through a path including the heat sink 104, the back surface of the mounting portion 115, the connecting spring 121, the copper foil layer 106, and the screw 112, as indicated by an arrow shown in FIG. 2. Thus, the static electricity escapes to the GND, so that no static electricity is applied to the semiconductor device 102 or surrounding semiconductor devices. Accordingly, the electronic device 100 according to the present embodiment is configured to easily avoid electrostatic destruction.

As described above, the ESD countermeasure can be achieved by adding the connecting spring 121 to the fastener 105 for the heat sink 104. With such a configuration, even when a general fastener formed of a plastic material that is an insulating material is used, the ESD countermeasure can be achieved only by the addition of the connecting spring thereto. Thus, the device of such a configuration is low in the manufacturing cost. Consequently, the present embodiment is preferable.

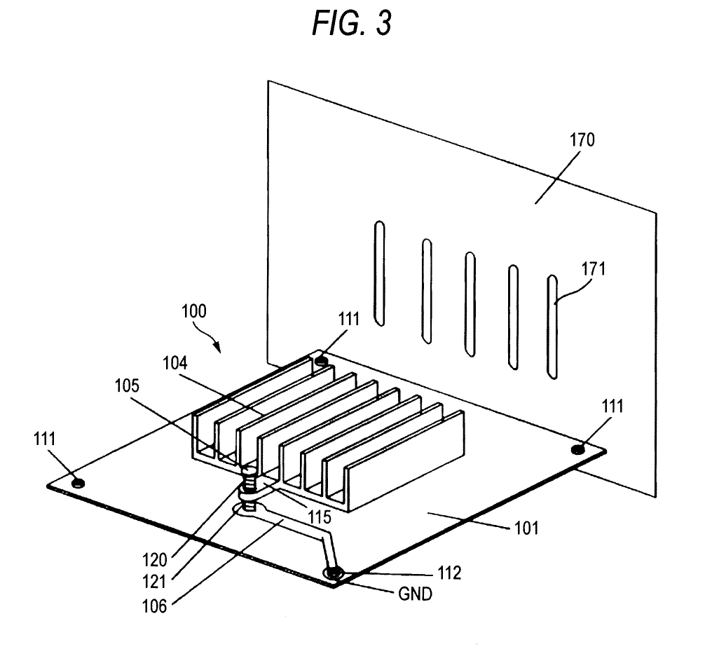

The invention is not limited to the above embodiment as it is, and can be implemented by modifying the constituent-elements thereof within the scope of the invention in an implementation step. For example, the above electronic device 100 can be disposed in various situations. For example, as illustrated in FIG. 3, the device can be configured so that a casing 170 accommodating the printed board 101, the heat sink 104, the semiconductor device 102, and the like is provided with a plurality of slits 171, and that the heat sink 104 is disposed in the vicinity of the slits 171. With such a configuration, external air hits the heat sink 104 well. Thus, heat radiation properties can be improved.

When the casing is provided with the constituent-elements such as the slits, static electricity accumulated in a human body can be discharged via the slits to the heat sink 104 provided in the casing. However, as described above, the present embodiment takes the ESD countermeasure. In addition, heat radiation effects can be further enhanced by mounting a cooling fan in the vicinity of the heat sink 104.

In the above embodiment, the thermally conductive sheet 103 is disposed between the heat sink 104 and the semiconductor device 102. However, the heat sink 104 and the semiconductor device 102 can be bonding-fixed with an adhesive-agent, a double-sided tape, or the like, without the thermally conductive sheet 103.

In the present embodiment, the heat sink 104 is connected to the GND via the copper foil layer 106 provided on the surface of the printed board 101. However, wire-like wiring can be used therefor. An example of usage of the above configuration is described below. For example, the above configuration is appropriately used for a television broadcast receiver. That is, in the television broadcast receiver, a tuner device for receiving a broadcast wave (broadcast signal) is provided. In addition, components such as a large number of circuits are mounted therein, which configure a video signal processing system for displaying a video in a video display portion using the broadcast signal. Among the various circuit components, particularly, a semiconductor integrated circuit configuring a decoder device generates heat due to high-speed digital data processing. Accordingly, the configuration according to the present embodiment taking the heat radiation countermeasure, and the ESD countermeasure is very effective in such a semiconductor integrated circuit.

The invention implemented as the present embodiment can widely be applied to electronic devices required to take the heat radiation measurement and the ESD measurement. In the present embodiment, the semiconductor device and the heat sink are sequentially stacked on the printed board. A stacking order can appropriately be modified according to the design of a chip structure of the semiconductor device. A member with good thermal conductivity can additionally be interposed between the semiconductor device and the heat sink. Thus, the semiconductor device and the heat sink can be disposed so as not to be close to each other but as to be spaced from each other.

Although the embodiments according to the present invention have been described above, the present invention may not be limited to the above-mentioned embodiments but can be variously modified. Components disclosed in the aforementioned embodiments may be combined suitably to form various modifications. For example, some of all components disclosed in the embodiments may be removed or may be appropriately combined.

Additional advantages and modifications will readily occur to those skilled in the art. Therefore, the invention in its broader aspects may not be limited to the specific details and representative embodiments shown and described herein. Accordingly, various modifications may be made without departing from the spirit or scope of the general inventive concept as defined by the appended claims and their equivalents.

What is claimed is:

1. An electronic apparatus comprising:
a semiconductor device comprising an electrically conductive portion to be grounded, the semiconductor device being configured to be mounted on a circuit board;
a heat sink configured to radiate heat generated by the semiconductor device;
a fastener configured to fasten the heat sink to the circuit board; and
a first spring member wound around the fastener to electrically connect the heat sink to the electrically conductive portion.

2. The apparatus of claim 1,
wherein the fastener comprises a head portion and a shank portion,
wherein the apparatus further comprises:
a mounting portion comprising an opening into which the fastener is inserted; and
a second spring member provided between the head portion and one of surfaces of the mounting portion, and
wherein the first spring member is provided between the other surface of the mounting portion and the electrically conductive portion.

3. The apparatus of claim 2,
wherein the first spring member has smaller elastic force than that of the second spring member.

4. The apparatus of claim 2,
wherein the heat sink is configured to comprise the mounting portion.

5. The apparatus of claim 4,
wherein an oxidation treatment is performed on a surface of the heat sink except at least a region of the mounting portion that contacts with the first spring member.

6. The apparatus of claim 1 further comprising:
a tuner device configured to receive a broadcast wave.

7. The apparatus of claim 6,
wherein the semiconductor device comprises a decoder device configured to decode a broadcast wave received by the tuner device.
